(19) United States
(12) Patent Application Publication
(10) Pub. No.: US 2021/0157043 A1
(43) Pub. Date: May 27, 2021

(54) DISPLAY DEVICE

(71) Applicant: SAMSUNG DISPLAY CO., LTD., Yongin-si (KR)

(72) Inventors: Beong-Hun BEON, Hwaseong-si (KR); Woo Suk JUNG, Cheonan-si (KR); Duk Jin LEE, Suwon-si (KR)

(21) Appl. No.: 16/935,518

(22) Filed: Jul. 22, 2020

(30) Foreign Application Priority Data
Nov. 25, 2019 (KR) 10-2019-0152404

(51) Int. Cl. G02B 5/30; G02B 1/14; G06F 1/16

(52) U.S. Cl. CPC G02B 5/3016; G06F 1/1609; G02B 1/14

(57) ABSTRACT

A display device includes: a display panel; a first adhesive layer disposed on the display panel; a polarization portion disposed on the first adhesive layer; a second adhesive layer disposed on the polarization portion; and a window disposed on the second adhesive layer, wherein the polarization portion includes a polarizer, and wherein the second adhesive layer is disposed on the polarizer.

### CROSS-REFERENCE TO RELATED APPLICATION

This application claims priority under 35 U.S.C. § 119 to Korean Patent Application No. 10-2019-0152404 filed in the Korean Intellectual Property Office on Nov. 25, 2019, the disclosure of which is incorporated by reference herein in its entirety.

### TECHNICAL FIELD

The present disclosure relates to a display device, and more particularly, to a display device including a polarization portion.

### DISCUSSION OF THE RELATED ART

A display device such as a liquid crystal display (LCD), an organic light emitting diode (OLED) display, an electrophoretic display, and the like generally includes a field generating electrode and electro-optical active layer. For example, the OLED display includes an organic emission layer as the electro-optical active layer. The field generating electrode may receive a data signal by being connected with a switch such as a thin film transistor, and the electro-optical active layer displays an image by converting the data signal to an optical signal.

The display device may include a display portion and an optical portion. The display portion may display an image and the optical portion may have an optical function. The optical portion may include, for example, a polarization portion that can convert a polarization state of light.

A display panel is limited in its portability and large screen display when using a relatively heavy and fragile glass substrate. Therefore, a flexible display device using a flexible substrate having a light weight and strong impact resistance and a flexible display panel has been under development. The flexible display device can be implemented in various forms, such as a curved display device, a bended display device, a foldable display device, a rollable display device, and a stretchable device.

### SUMMARY

According to an exemplary embodiment of the present invention, a display device includes: a display panel; a first adhesive layer disposed on the display panel; a polarization portion disposed on the first adhesive layer; a second adhesive layer disposed on the polarization portion; and a window disposed on the second adhesive layer, wherein the polarization portion includes a polarizer, and wherein the second adhesive layer is disposed on the polarizer.

In an exemplary embodiment of the present invention, the polarization portion further includes: at least one phase retarder; and a third adhesive layer disposed between the polarizer and the at least one phase retarder.

In an exemplary embodiment of the present invention, the polarizer is a linear polarizer, and the at least one phase retarder includes a λ/4 phase retarder.

In an exemplary embodiment of the present invention, the at least one phase retarder further includes a λ/2 phase retarder, and wherein the polarization portion further includes a fourth adhesive layer disposed between the λ/4 phase retarder and the λ/2 phase retarder.

In an exemplary embodiment of the present invention, the polarizer includes stretched polyvinyl alcohol and a dye.

In an exemplary embodiment of the present invention, the polarizer has a thickness of about 0.5 μm to about 10 μm.

In an exemplary embodiment of the present invention, the polarization portion has a thickness of about 5 μm to about 15 μm.

In an exemplary embodiment of the present invention, the polarization portion does not include a film or a member, which does not have a polarization function or a phase retardation function, on the third adhesive layer.

In an exemplary embodiment of the present invention, the at least one phase retarder includes a liquid crystal coating type of phase retarder.

In an exemplary embodiment of the present invention, at least one of the first adhesive layer or the second adhesive layer includes at least one of an optically clear adhesive (OCA), an optically clear resin (OCR), or a pressure sensitive adhesive (PSA).

In an exemplary embodiment of the present invention, the polarization portion includes an opening.

In an exemplary embodiment of the present invention, the display panel includes a light transmission portion corresponding to the opening, and any pixel including a thin film transistor is not formed in the light transmission portion.

In an exemplary embodiment of the present invention, the display device further includes an optical member overlapping the light transmission portion.

According to an exemplary embodiment of the present invention, a display device includes: a display panel; a first adhesive layer disposed on the display panel; a polarization portion disposed on the first adhesive layer; a second adhesive layer disposed on the polarization portion; and a window disposed on the second adhesive layer, wherein the polarization portion includes a polarizer, and at least one phase retarder disposed on a first side of the polarizer, wherein the polarizer includes stretched polyvinyl alcohol, wherein the second adhesive layer is disposed on a second side of the polarizer, and wherein the second side of the polarizer faces the first side of the polarizer.

In an exemplary embodiment of the present invention, the polarizer has a thickness of about 0.5 μm to about 10 μm.

In an exemplary embodiment of the present invention, the polarization portion has a thickness of about 5 μm to about 15 μm.

In an exemplary embodiment of the present invention, the polarization portion does not include a film or a member that does not have a polarization function or a phase retardation function.

According to an exemplary embodiment of the present invention, a method for manufacturing a display device includes: coating polyvinyl alcohol on a first base film and drying the first base film; forming a polarizer that includes a first side and a second side, which face each other, by stretching the coated first base film, wherein the first base film is disposed on the second side of the polarizer; forming at least one phase retarder; attaching the first side of the polarizer and the at least one phase retarder to each other; removing the first base film from the second side of the polarizer; forming a first adhesive layer on the second side of the polarizer; and attaching a window to the first adhesive layer.

In an exemplary embodiment of the present invention, the forming the at least one phase retarder includes: forming a first phase retarder on a second base film; forming a second phase retarder on a third base film; attaching the first phase retarder and the second phase retarder to each other, wherein a second adhesive layer is disposed between the first phase retarder and the second phase retarder; and peeling off the second base film, wherein the attaching of the first side of the polarizer and the at least one phase retarder to each other includes attaching the polarizer and the first phase retarder to each other, and wherein a third adhesive layer is disposed between the first side of the polarizer and the first phase retarder.

In an exemplary embodiment of the present invention, the method for manufacturing the display device further includes: manufacturing a display panel; and attaching the second phase retarder and the display panel to each other, wherein a fourth adhesive layer is disposed between the second phase retarder and the display panel.

In an exemplary embodiment of the present invention, the method for manufacturing the display device further includes: forming a fifth adhesive layer on the first phase retarder;

and forming a sixth adhesive layer on the second phase retarder, wherein when the first phase retarder and the second phase retarder are attached to each other, the fifth adhesive layer and the sixth adhesive layer are stacked on each other to form the second adhesive layer.

According to an exemplary embodiment of the present invention, a display device includes: a display panel; a first adhesive layer disposed on the display panel; a polarization portion disposed on the first adhesive layer and including a first phase retarder and a polarizer disposed on the first phase retarder, wherein the polarization portion does not include a film or a member that does not have a polarization function or a phase retardation function; a second adhesive layer disposed on the polarization portion; and a window disposed on the second adhesive layer.

### BRIEF DESCRIPTION OF THE DRAWINGS

FIG. 1 is a cross-sectional view of a polarization portion included in a display device according to an exemplary embodiment of the present invention;

FIG. 2 is a cross-sectional view of a display device according to an exemplary embodiment of the present invention;

FIG. 3 illustrates a process for manufacturing a part of a polarization portion in a manufacturing method of a display device according to an exemplary embodiment of the present invention;

FIG. 4 illustrates a process for manufacturing a part of a polarization portion in a manufacturing method of a display device according to an exemplary embodiment of the present invention;

FIG. 5 illustrates a process for manufacturing a part of a polarization portion in a manufacturing method of a display device according to an exemplary embodiment of the present invention;

FIG. 6 is a cross-sectional view of the polarization portion manufactured from the manufacturing process shown in FIG. 5;

FIG. 7, FIG. 8, FIG. 9, FIG. 10, and FIG. 11 are cross-sectional views of a polarization portion included in a display device according to an exemplary embodiment of the present invention; and

FIG. 12 is a cross-sectional view of a display device according to an exemplary embodiment of the present invention.

### DETAILED DESCRIPTION OF THE EMBODIMENTS

Hereinafter, exemplary embodiments of the present invention will be described in detail with reference to the accompanying drawings. The present invention may be embodied in many different forms, and should not be construed as limited to the exemplary embodiments set forth herein.

Accordingly, the drawings and description are to be regarded as illustrative in nature and not restrictive. Like reference numerals may designate like elements throughout the specification, and thus, repetitive descriptions may be omitted.

Further, in the drawings, the size and thickness of each element may be exaggerated for clarity, but the present invention is not limited thereto.

It will be understood that when an element such as a layer, film, region, or substrate is referred to as being “on” another element, it can be directly on the other element or intervening elements may also be present. In addition, when an element is referred to as being “directly on” another element, there are no intervening elements present.

Throughout the specification, “in a plan view” refers to a view observing a plane parallel to two directions (e.g., first direction DR1 and second direction DR2) intersecting each other (also referred to as a plane view) from above, and “in a cross-sectional view” refers to a view from a side of a cross-section of a target part, taken by vertically cutting an object portion.

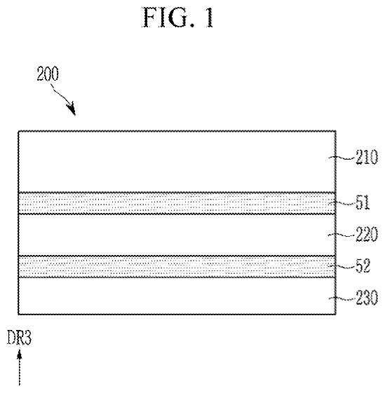

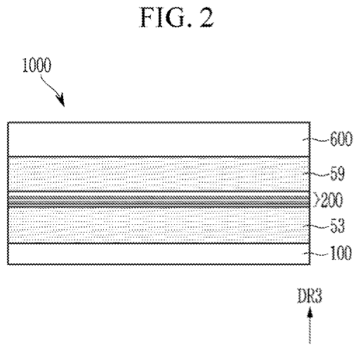

First, a polarizer and a display device according to an exemplary embodiment of the present invention will be described with reference to FIG. 1 and FIG. 2.

FIG. 1 is a cross-sectional view of a polarization portion included in a display device according to an exemplary embodiment of the present invention, and FIG. 2 is a cross-sectional view of a display device according to an exemplary embodiment of the present invention.

Referring to FIG. 1, a polarization portion 200 included in a display device according to an exemplary embodiment of the present invention may be, for example, a circular polarizer or an elliptical polarizer for converting incident light into circularly polarized or elliptically polarized light. The polarization portion 200 includes a polarizer 210, at least one phase retarder 220 and 230, and adhesive layers 51 and 52.

The polarizer 210 may be a straight line polarizer that is disposed at the uppermost side of polarization portion 200 and converts incident light into linearly polarized light. The polarizer 210 transmits light that is vibrating in a transmissive axis direction, and blocks a light component that is vibrating perpendicular to the transmissive axis direction.

The polarizer 210 may include, for example, polyvinyl alcohol (PVA) as a polarization material. For example, the polarizer 210 may have a polarization function in which a dichroism dye such as iodine is orientated and adsorbed on a layer containing stretched polyvinyl alcohol and may have a polarization function. The polarizer 210 may be provided in the form of a film, or may be provided as a liquid coating-type polarizer that includes aligned liquid crystals.

A thickness of the polarizer 210 in a third direction DR3 may be for example about 0.5 μm to about 10 μm.

At least one phase retarder 220 and 230 may be a λ/2 phase retarder or a λ/4 phase retarder. For example, the phase retarders 220 and 230 may include λ/2 phase retarder 220 or a λ/4 phase retarder 230. The λ/2 phase retarder 220 assigns a phase difference of λ/2 in a direction that perpendicularly crosses a progress direction of incident light, and the λ/4 phase retarder 230 assigns a phase difference of λ/4 in a direction that perpendicularly crosses the progress direction of the incident light to convert linearly polarized light to circularly polarized light.

For example, each of the λ/2 phase retarder 220 and the λ/4 phase retarder 230 may a liquid coated-typed phase retarder that includes cured liquid crystal aligned in a predetermined arrangement. In addition, each of the λ/2 phase retarder 220 and the λ/4 phase retarder 230 may be a stretched film-type phase retarder.

A thickness of the λ/2 phase retarder 220 in the third direction DR3 and a thickness of the λ/4 phase retarder 230 in the third direction DR3 may each be, for example, about 0.5 μm to about 5 μm.

A thickness of the λ/2 phase retarder 220 in the third direction DR3 may be greater than or equal to a thickness of the λ/4 phase retarder 230 in the third direction DR3. For example, when the thickness of the λ/2 phase retarder 220 in the third direction DR3 is about 2 μm, the thickness of the λ/4 phase retarder 230 may be about 1 μm.

As shown in the present embodiment of FIG. 1, when the polarization portion 200 includes the λ/2 phase retarder 220, linearly polarized light of an RGB (e.g., red, green, and blue) wavelength is separated such that a wideband λ/4 phase retardation effect can be acquired.

The λ/2 phase retarder 220 may be omitted.

The adhesive layer 51 is disposed between the polarizer 210 and the λ/2 phase retarder 220 for adherence therebetween, and the adhesive layer 52 is disposed between the λ/2 phase retarder 220 and the λ/4 phase retarder 230 for adherence therebetween.

The adhesive layers 51 and 52 may include at least one among an optically clear adhesive (OCA), an optically clear resin (OCR), a pressure sensitive adhesive (PSA), or an ultraviolet (UV) curing adhesive, and such a material may be equally applied to other adhesive layers, which will be described later.

A thickness of each of the adhesive layers 51 and 52 in the third direction DR3 may be, for example, about 0.3 μm to about 2 μm, but the present invention is not limited thereto.

The polarization portion 200 according to an exemplary embodiment of the present invention may not further include another transparent film or member that does not have a polarization function or a phase retardation function. However, the polarization portion 200 according to the present embodiment includes adhesive layers 51 and 52. Accordingly, the thickness of the polarization portion 200 in the third direction DR3 may become very thin, and for example, may be about 2 μm to about 25 μm. For example, the thickness of the polarization portion 200 may become as thin as about 2 μm to about 15 μm.

The polarization portion 200 may be in the form of a thin flexible film.

Referring to FIG. 2, a display device 1000 according to an exemplary embodiment of the present invention may include a display panel 100 that can display an image, an adhesive layer 53 disposed on the display panel 100, a polarization portion 200 disposed on the adhesive layer 53, an adhesive layer 59 disposed on the polarization portion 200, and a window 600 disposed on the adhesive layer 59.

The display panel 100 may include a plurality of pixels and a plurality of transistors, and may further include a touch sensor that can sense a touch or hovering of an external object.

Since the adhesive layer 59 is disposed on the polarization portion 200, the adhesive layer 59 contacts the polarizer 210 of the polarization portion 200, and the window 600 may be directly attached to the polarization portion 200 through the adhesive layer 59.

For example, between the window 600 and the polarizer 210, an additional transparent film for protection of the polarizer 210 during a manufacturing process of the display device or an additional substrate or film that does not have a polarization function or a phase retardation function is not provided, thereby further reducing a thickness of the display device 1000.

The polarization portion 200 reduces reflectance of external light incident from the outside to prevent the reflected light from being visually recognized.

For example, external light converted to right-circularly polarized light while passing through the polarization portion 200 is left-circularly polarized by being reflected by an electrode or a wire of the display panel 100, and when the reflected left-circularly polarized light is incident on the polarization portion 200 again, the reflected left-circularly polarized light experiences destructive interference with the right-circularly polarized light such that the reflected light can be prevented from being visually recognized from the outside by, for example, a user. Therefore, only light according to an image signal is transmitted through the polarization portion 200 in the display panel 100 such that image quality to be displayed may be increased.

The window 600 may include at least one window, and each window may include a polymer such as plastic and the like or an insulation material such as glass and the like. An adhesive layer may be disposed between a plurality of window layers stacked in the third direction DR3.

The display panel 100 and the display device 1000 including the display panel 100 may include a flexible substrate having flexibility and thus may be flexible. For example, the display device 1000 may include a curved display device that can be curved, a bent display device that can be bendable, a rollable display device that can be rolled like a scroll, a stretchable display device that can be stretched, and the like. However, the present invention is not limited thereto, and the display panel 100 and the display device 1000 may be rigid and thus may have a fixed shape because of low flexibility.

The type of the display panel 100 may vary. For example, the display panel 100 may include a liquid crystal panel, an organic light emitting panel, an electrophoretic display panel, and the like. The display panel 100 may include a field generating electrode and an electro-optical active layer. For example, the organic light emitting panel may include an organic emission layer as the electro-optical active layer. The field generating electrode is connected with a switch, such as a thin film transistor and the like, and thus, the field generating electrode may be applied with a data signal. The electro-optical active layer converts such a data signal to an optical display to display an image.

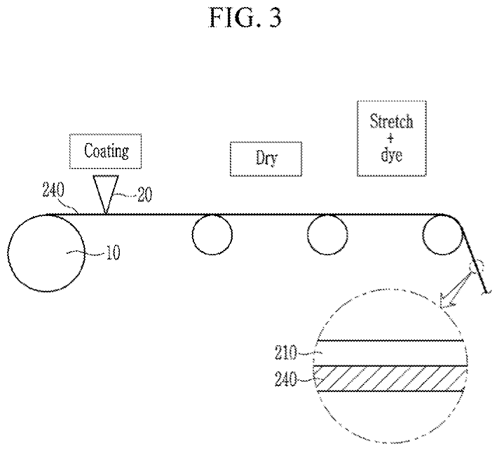

Hereinafter, a polarization portion according to an exemplary embodiment of the present invention and a method for manufacturing a display device including the polarization portion will be described with reference to FIG. 3 to FIG. 11, together with the above-described FIG. 1 and FIG. 2.

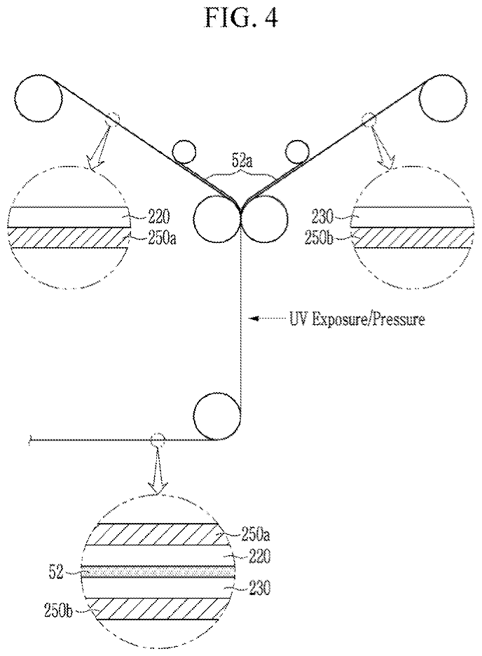

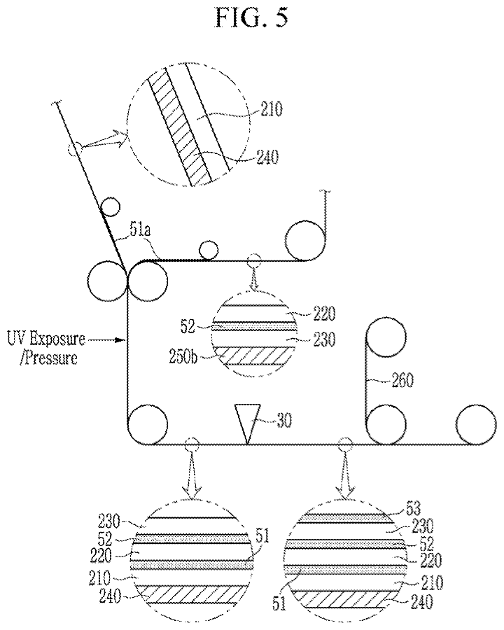

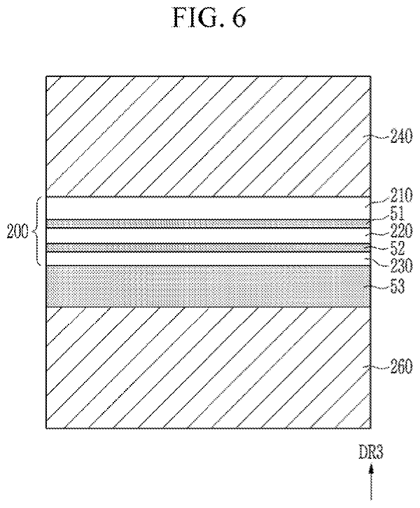

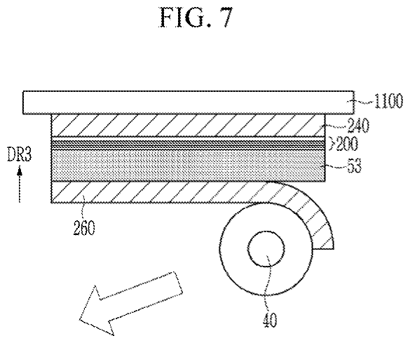

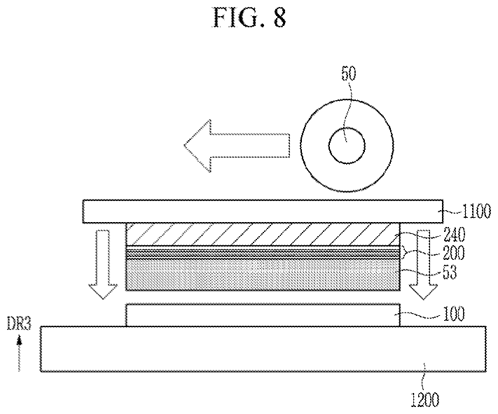

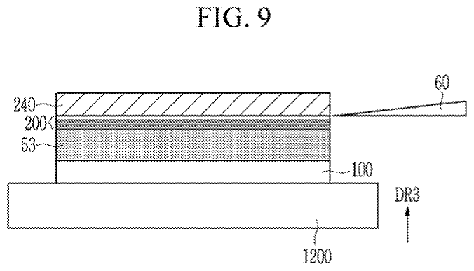

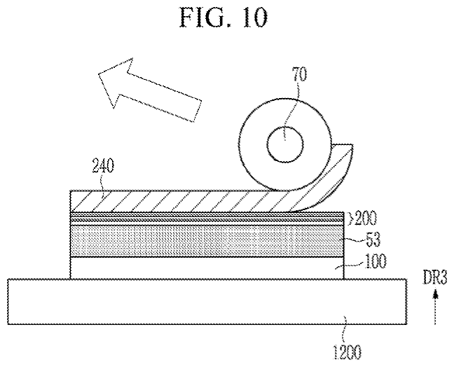

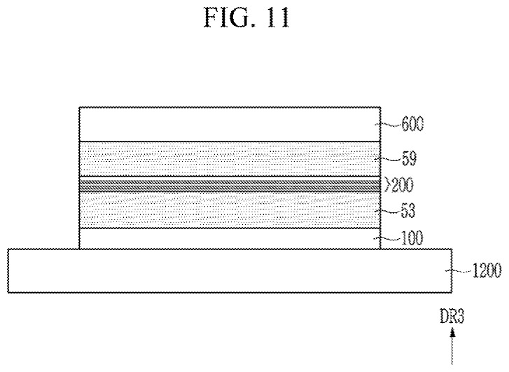

FIG. 3 illustrates a process for manufacturing a part of a polarization portion in a manufacturing method of a display device according to an exemplary embodiment of the present invention. FIG. 4 illustrates a process for manufacturing a part of a polarization portion in a manufacturing method of a display device according to an exemplary embodiment of the present invention. FIG. 5 illustrates a process for manufacturing a part of a polarization portion in a manufacturing method of a display device according to an exemplary embodiment of the present invention. FIG. 6 is a cross-sectional view of the polarization portion manufactured from the manufacturing process shown in FIG. 5. FIG. 7, FIG. 8, FIG. 9, FIG. 10, and FIG. 11 sequentially illustrate a process of a manufacturing method of a display device according to an exemplary embodiment of the present invention after manufacturing the polarization portion in the manufacturing process shown in FIG. 6.

Referring to FIG. 3, the above-described polarization material of the polarizer 210, for example, PVA, may be coated on an unstretched base film 240 separated from a roll 10 by using a coating device 20, and may then be dried.

The base film 240 may be, for example, a polymer film that can be stretched, and for example, may be a polyethylene terephthalate (PET) film.

The polarization material of the polarizer 210 used for coating, for example, PVA, may be coated to have a thickness of about 5 μm to about 30 μm, but the present invention is not limited thereto.

Next, the coated base film 240 is stretched. For example, the coated base film 240 may be stretched in a widthwise direction or a lengthwise direction at a high temperature or high temperature and humidity condition. The stretch ratio may be approximately 2 to approximately 10.

During, after, or before the stretching of the coated base film 240, a dye may be adsorbed (or dyed) into the base film 240. A dye adsorption method may include, for example, adsorbing the dye by immersing the coated base film 240 in potassium iodide (KI). For example, the coated base film 240 may be stretched while adsorbing the dye. As an additional example, the coated base film 240 may be stretched while adsorbing the dye after partially stretching the base film 240, or, for example, the base film 240 may be stretched after the dye is adsorbed to the coated base film 240.

In the present embodiment, the base film 240 is stretched or the dye is adsorbed by the base film 240 after coating a polarization material, such as PVA, of the polarizer 210 on the base film 240, and thus, compared to a conventional polarizer formed by stretching and dye adsorption of a polyvinyl alcohol (PVA) film, a polarizer 210 having a reduced thickness can be formed.

In addition, when the polarizer 210 is formed by coating polyvinyl alcohol (PVA) and then stretching it, the polarizer 210 may not have a stress to shrink compared to conventional stretching of a polyvinyl alcohol (PVA) film which does have a stress to shrink or a force to contract.

Next, an alignment agent is coated to base films 250a and 250b such as triacetate cellulose (TAC), cellulous acetate propionate (CAP), wide view-TAC (WV-TAC), PET, and the like, and then an alignment layer is formed through optical alignment or physical rubbing.

Next, a liquid crystal composition is coated and photo-cured on the base films 250a and 250b having the alignment layer formed thereon, thereby forming a liquid crystal coating type of λ/2 phase retarder 220 and λ/4 phase retarder 230, each containing the oriented liquid crystals.

Next, referring to FIG. 4, an adhesive material is coated on each of the λ/2 phase retarder 220 and the λ/4 phase retarder 230 such that adhesive layers 52a are formed on each of the λ/2 phase retarder 220 and the λ/4 phase retarder 230. The adhesive layer 52a may include, for example, an ultraviolet (UV) curing adhesive or a pressure sensitive adhesive (PSA).

Next, the two base films 250a and 250b are compressed such that the adhesive layer 52a on the λ/2 phase retarder 220 and the adhesive layer 52a on the λ/4 phase retarder 230 contact each other and are stacked on each other, and then, the adhesive layers 52a are cured by irradiating ultraviolet (UV) rays or applying a pressure to form the adhesive layer 52 between the λ/2 phase retarder 220 and the λ/4 phase retarder 230.

Thus, a film that includes the λ/2 phase retarder 220 and the λ/4 phase retarder 230 disposed between the two base films 250a and 250b, and further includes the adhesive layer 52 disposed between the λ/2 phase retarder 220 and the λ/4 phase retarder 230 can be formed.

Next, referring to FIG. 5, the base film 250a that contacts the λ/2 phase retarder 220 is peeled off from the film formed as shown in FIG. 4. For example, the base film 250a is removed from the λ/2 phase retarder 220.

Subsequently, an adhesive material is coated on each of the polarizer 210, disposed on the base film 240, formed in FIG. 3, and the λ/2 phase retarder 220 from which the base film 250a is peeled off from such that the adhesive layer 51a is formed on each of the polarizer 210 and the λ/2 phase retarder 220. The adhesive layer 51a may include, for example, an ultraviolet (UV) curing adhesive or a pressure sensitive adhesive (PSA).

The two base films 240 and 250b are compressed such that the adhesive layer 51a on the polarizer 210 and the adhesive layer 51a on the λ/2 phase retarder 220 contact each other and are stacked on each other, and then, the adhesive layers 51a are cured by irradiating ultraviolet (UV) rays or applying a pressure to form the adhesive layer 51 between the polarizer 210 and the λ/2 phase retarder 220.

Next, the base film 250b that contacts the λ/4 phase retarder 230 is removed by being peeled off.

Thus, a film including the base film 240, the polarizer 210, the adhesive layer 51, the λ/2 phase retarder 220, the adhesive layer 52, and the λ/4 phase retarder 230, which are sequentially stacked may be formed.

Next, an adhesive material is coated on the λ/4 phase retarder 230 by using a coating device 30 such that the adhesive layer 53 is formed on the λ/4 phase retarder 230, and a release film 260 is attached to the adhesive layer 53. The release film 260 is provided on the adhesive layer 53 to protect the films that have been formed so far before attaching the films to the display panel.

Thus, as shown in FIG. 6, a film that includes the release film 260, the adhesive layer 53, the λ/4 phase retarder 230, the adhesive layer 52, the λ/2 phase retarder 220, the adhesive layer 51, the polarizer 210, and the base film 240, which are sequentially stacked, may be formed.

For example, a film used in the stretching process of the polarizer 210 may be left to be used as the base film 240, or a protective film such as acrylic may be attached after removing the base film 240.

Next, referring to FIG. 7, the release film 260 is removed.

To remove the release film 260, for example, as shown in FIG. 6, the outer surface of the base film 240 shown in FIG. 6 is attached and fixed to a fixing portion 1100. For example, the fixing portion 1100 may include a fixed adhesive sheet or vacuum pad. For example, the release film 260 is attached to a peeling roller 40 that includes adhesive tape, and the release film 260 is peeled off to remove the release film 260 from the polarizer 210.

Next, referring to FIG. 8, a film, from which the release film 260 is removed by being peeled off in FIG. 7, is placed on the display panel 100 that is fixed on a stage 1200 and then pressed such that the polarization portion 200 is attached onto the display panel 100. In this case, a roller 50 may be used to press the polarization portion 200 against the stage 1200. The display panel 100 and the polarization portion 200 may be attached to each other through the adhesive layer 53 disposed therebetween. For example, the λ/4 phase retarder 230 of the polarization portion 200 may be attached to the display panel 100 through the adhesive layer 53.

Next, referring to FIG. 9, a portion of an edge between the base film 240 and the polarization portion 200 may be lifted by creating a starting point for peeling of the base film 240. For example, the peeling start point may be created using a precision knife 60 or a laser.

Next, referring to FIG. 10, the base film 240 attached to the polarization portion 200 is removed by being peeled off. For example, the base film 240 is attached to a peeling roller 70 including adhesive tape, and then, the base film 240 may be peeled off by using the peeling roller 70. As previously described, when a protective film such as acryl is attached instead of the base film 240, the protective film may be peeled off in the present stage.

Next, referring to FIG. 11, an adhesive layer 59 is formed on the polarization portion 200 from which the base film 240 or the protective film is peeled off, and then, a window 600 is attached to the adhesive layer 59. As a result, the above-described display device as shown in FIG. 2 may be manufactured.

As previously described, in the display device according to an exemplary embodiment of the present invention, the polarization portion 200, attached through the adhesive layer 53 to the display panel 100, may not include an additional protective film or protective member. For example, the polarization portion 200 may include optical function layers such as a polarizer 210, a λ/2 phase retarder 220, and a λ/4 phase retarder 230, and adhesive layers 51 and 52 disposed on the optical function layers. The window 600 is attached to the polarization portion 200 through the adhesive layer 59 for protection of the display device. For example, the window 600 may be directly disposed on the adhesive layer 59 to be attached to the polarization portion 200. For example, an additional protective film or protective member is not provided between the polarizer 210 of the polarization portion 200 and the window 600. Accordingly, a very thin polarization portion 200 and display device may be provided. Therefore, it is possible to reduce stress that can be caused when the display device is folded or deformed compared to a thick polarization portion and display device.

When the polarizer 210 is formed by coating polyvinyl alcohol (PVA) and then stretching the base film 240 as previously described, the polarizer 210 may not have a stress to shrink as compared to a conventional stretching of a polyvinyl alcohol (PVA) film. When the polyvinyl alcohol (PVA) film is stretched and used as in the prior art, residual stress exists in the film, and when exposed to high temperature or humidity conditions, the film may exhibit a contraction phenomenon to return to its original form. However, according to an exemplary embodiment of the preset invention, the polarizer 210 formed by coating does not have contractility, and thus a failure due to contraction of the polarizer 210 does not occur even through the base film on the polarizer 210 is removed before attaching the window 600, and the thickness of the polarization portion 200 and the display device can be further reduced. However, according to the present embodiment, even though the base film 240 on the polarizer 210 is removed before the window 600 is attached, because the polarizer 210 formed of the coating is not shrinkable, the shrinkage of the polarizer 210 does not occur. Therefore, no defect occurs, and the thickness of the polarization unit 200 and the display device can be further reduced.

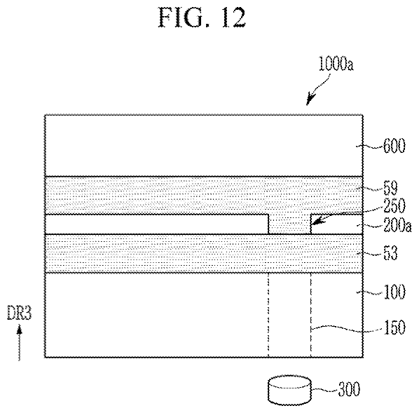

Next, referring to FIG. 12, a display device according to an exemplary embodiment of the present invention will be described.

FIG. 12 is a cross-sectional view of a display device according to an exemplary embodiment of the present invention.

Referring to FIG. 12, a display device 1000a according to an exemplary embodiment of the present invention may be almost the same as the above-described display device 1000, except that the display device 1000a includes a polarization portion 200a instead of the above-described polarization portion 200.

The polarization portion 200a is almost the same as the above described polarization portion 200, except that the polarization portion 200a includes an opening 250.

The display device 1000a may include at least one optical member 300 disposed below the display panel 100. For example, the optical member 300 may include a camera, a flash, an optical sensor, and the like.

The display panel 100 may include at least one light transmission portion 150. For example, a pixel including a thin film transistor may not be formed in the light transmission portion 150. Light may pass through the display panel 100 in a third direction DR3 by passing through the light transmission portion 150.

The optical member 300 may emit light through the light transmission portion 150 of the display panel 100 or may receive incident light through the light transmission portion 150. For example, the optical member 300 may overlap the light transmission portion 150 of the display panel 150.

The opening 250 of the polarization portion 200a may increase transmittance of light transmitted therethrough by being located to correspond to the light transmission portion 150. For example, the opening 250 may overlap the light transmission portion 150.

According to the present embodiment, like the above-described polarization portion 200, a thickness of the polarization portion 200a in the third direction DR3 may be reduced such that the polarization portion 200a may be very thin. Therefore, variations in a thickness of the polarization portion 200a may be very small, so that the thickness variations of the adhesive layer 59 disposed on the polarization portion 200a may be small. For example, the thicknesses of the polarization portion 200a and the adhesive layer 59 may be substantially constant. In addition, lifting of the adhesive layer 59 according to variations in thickness (e.g., a thickness deviation) and/or poor adhesion of the window 600 can be prevented.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A display device comprising:
a display panel;
a first adhesive layer disposed on the display panel;
a polarization portion disposed on the first adhesive layer;
a second adhesive layer disposed on the polarization portion; and
a window disposed on the second adhesive layer,
wherein the polarization portion comprises a polarizer, and
wherein the second adhesive layer is disposed on the polarizer.

2. The display device of claim 1, wherein the polarization portion further comprises:
at least one phase retarder; and
a third adhesive layer disposed between the polarizer and the at least one phase retarder.

3. The display device of claim 2, wherein the polarizer is a linear polarizer, and the at least one phase retarder comprises a λ/4 phase retarder.

4. The display device of claim 3, wherein the at least one phase retarder further comprises a λ/2 phase retarder, and
wherein the polarization portion further comprises a fourth adhesive layer disposed between the λ/4 phase retarder and the λ/2 phase retarder.

5. The display device of claim 3, wherein the polarizer comprises stretched polyvinyl alcohol and a dye.

6. The display device of claim 5, wherein the polarizer has a thickness of about 0.5 μm to about 10 μm.

7. The display device of claim 3, wherein the polarization portion has a thickness of about 5 μm to about 15 μm.

8. The display device of claim 3, wherein the polarization portion does not include a film or a member, which does not have a polarization function or a phase retardation function, on the third adhesive layer.

9. The display device of claim 3, wherein the at least one phase retarder comprises a liquid crystal coating type of phase retarder.

10. The display device of claim 1, wherein at least one of the first adhesive layer or the second adhesive layer comprises at least one of an optically clear adhesive (OCA), an optically clear resin (OCR), or a pressure sensitive adhesive (PSA).

11. The display device of claim 1, wherein the polarization portion comprises an opening.

12. The display device of claim 11, wherein the display panel comprises a light transmission portion corresponding to the opening, and
any pixel including a thin film transistor is not formed in the light transmission portion.

13. The display device of claim 12, further comprising an optical member overlapping the light transmission portion.

14. A display device comprising:
a display panel;
a first adhesive layer disposed on the display panel;
a polarization portion disposed on the first adhesive layer;
a second adhesive layer disposed on the polarization portion; and
a window disposed on the second adhesive layer,
wherein the polarization portion comprises a polarizer, and at least one phase retarder disposed on a first side of the polarizer, wherein the polarizer includes stretched polyvinyl alcohol,
wherein the second adhesive layer is disposed on a second side of the polarizer, and wherein the second side of the polarizer faces the first side of the polarizer.

15. The display device of claim 14, wherein the polarizer has a thickness of about 0.5 μm to about 10 μm.

16. The display device of claim 14, wherein the polarization portion has a thickness of about 5 μm to about 15 μm.

17. The display device of claim 14, wherein the polarization portion does not include a film or a member that does not have a polarization function or a phase retardation function.

18. A method for manufacturing a display device, comprising:
coating polyvinyl alcohol on a first base film and drying the first base film;
forming a polarizer that includes a first side and a second side, which face each other, by stretching the coated first base film, wherein the first base film is disposed on the second side of the polarizer;
forming at least one phase retarder;
attaching the first side of the polarizer and the at least one phase retarder to each other;
removing the first base film from the second side of the polarizer;
forming a first adhesive layer on the second side of the polarizer; and
attaching a window to the first adhesive layer.

19. The method for manufacturing the display device of claim 18, wherein the forming the at least one phase retarder comprises:
forming a first phase retarder on a second base film;
forming a second phase retarder on a third base film;
attaching the first phase retarder and the second phase retarder to each other, wherein a second adhesive layer is disposed between the first phase retarder and the second phase retarder; and
peeling off the second base film,
wherein the attaching of the first side of the polarizer and the at least one phase retarder to each other comprises attaching the polarizer and the first phase retarder to each other, and wherein a third adhesive layer is disposed between the first side of the polarizer and the first phase retarder.

20. The method for manufacturing the display device of claim 19, further comprising:
manufacturing a display panel; and
attaching the second phase retarder and the display panel to each other, wherein a fourth adhesive layer is disposed between the second phase retarder and the display panel.
